(19) United States
(12) Patent Application Publication
(10) Pub. No.: US 2025/0316528 A1
(43) Pub. Date: Oct. 9, 2025

(54) METHOD FOR DEBONDING WAFER

(71) Applicant: Qorvo US, Inc., Greensboro, NC (US)

(72) Inventors: Krishna Chetry, Richardson, TX (US); Michael Carroll, Jamestown, NC (US)

(21) Appl. No.: 19/046,768

(22) Filed: Feb. 6, 2025

Related U.S. Application Data
(60) Provisional application No. 63/631,407, filed on Apr. 8, 2024.

(51) Int. Cl. H01L 21/762

(52) U.S. Cl. CPC H01L 21/76254

(57) ABSTRACT

A method for debonding carrier and device wafer assemblies comprises the following steps. A carrier wafer assembly is provided having a carrier wafer and a carrier oxide layer over the carrier wafer, wherein the carrier wafer comprises a planar implantation zone below the carrier oxide layer. A device wafer assembly is provided having a handle wafer, a device layer on the handle wafer, and a device oxide layer on the device layer. The device layer has at least one semiconductor device formed therein. The carrier wafer assembly is bonded to the device wafer assembly such that the carrier oxide layer is bonded to the device oxide layer to form a final device precursor. The final device precursor is annealed to structurally weaken the carrier wafer along the planar implantation zone. The carrier wafer assembly is separated from the final device precursor at the planar implantation zone.

This application claims the benefit of U.S. provisional patent application Ser. No. 63/631,407, filed Apr. 8, 2024, the disclosure of which is incorporated herein by reference in its entirety.

### FIELD OF THE DISCLOSURE

The present disclosure relates to wafer level processing in general and an approach for debonding carrier and device wafer assemblies.

### BACKGROUND

In back-end processing of wafers, bonding and de-bonding of wafers are very critical to offer mechanical support to thin or to-be-thinned wafers. These processes are especially important for three-dimensional integrated circuits (3D ICs), power devices, and the handling of very fragile substrates. In all these processes, temporary bonding techniques are used to allow processing on the thinned device wafer before debonding the device wafer from the carrier wafer. With current technology, there are several key challenges in the temporary bonding techniques, which generally use an adhesive layer due to an incompatible interface layer between polymer and semiconductor material.

### SUMMARY

The present disclosure relates to a method for debonding carrier and device wafer assemblies. In one non-limiting embodiment, a method comprises the following steps. A carrier wafer assembly is provided having a carrier wafer and a carrier oxide layer over the carrier wafer, wherein the carrier wafer comprises a planar implantation zone below the carrier oxide layer. A device wafer assembly is provided having a handle wafer, a device layer on the handle wafer, and a device oxide layer on the device layer. The device layer has at least one semiconductor device formed therein. The carrier wafer assembly is bonded to the device wafer assembly such that the carrier oxide layer is bonded to the device oxide layer to form a final device precursor. The final device precursor is annealed to structurally weaken the carrier wafer along the planar implantation zone. The carrier wafer assembly is separated from the final device precursor at the planar implantation zone.

In one embodiment, the carrier wafer is implanted with an implant material to form the planar implantation zone. The implant material may comprise hydrogen.

In one embodiment, planar implantation zone is between four (4) and twenty (20) nanometers below the top surface of the carrier oxide layer.

In one embodiment, the implant material comprises hydrogen.

In one embodiment, the carrier oxide layer has a thickness in a range of 4 to 20 nanometers.

In one embodiment, the carrier oxide layer comprises silicon dioxide (SiO2).

In one embodiment, the device oxide layer comprises silicon dioxide (SiO2).

In one embodiment, both the carrier and device oxide layers comprise silicon dioxide (SiO2).

In one embodiment, the device layer is a complementary metal oxide semiconductor device structure that provides at least one CMOS device.

In one embodiment, the steps further include removing at least a portion of the handle wafer from a backside of the device wafer assembly.

In one embodiment, the steps further include providing a mold compound over the backside of the device wafer assembly after a portion of the handle wafer is removed from the backside of the device wafer assembly.

In one embodiment, a portion of the handle wafer is removed, and the mold compound is provided prior to separating the carrier wafer assembly from the final device precursor at the planar implantation zone.

In one embodiment, the step of bonding the carrier wafer assembly to the device wafer occurs at or below 350 Celsius.

In one embodiment, the step of separating the carrier wafer assembly from the final device precursor occurs at or below 400 Celsius.

In one embodiment, a semiconductor device formed by any of the above processes is provided.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIGS. 1A through 1I illustrate an exemplary wafer fabrication process according to one embodiment of the disclosure.

FIG. 2 is a cross section of a wafer with a microcrack along a planar implantation zone according to one embodiment of the disclosure.

FIG. 3 is a block diagram of an electrical power system according to one embodiment of the disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In all wafer backside processes, temporary bonding techniques are used where an adhesive layer is used to attach the functional device wafers to carrier wafers. After the completion of the backside process, the carrier wafer is detached from the processed device wafer by a debonding technique. The key challenges in traditional bonding and debonding processes are as follows. First, adhesive materials are generally made from polymers and the polymers are incompatible with the semiconductor systems. Second, the interface between adhesive material and silicon (Si) surface leads to defects and voids. Third, the adhesive materials are coated using a spin coating technique, which leads to uncontrollable uniformity and roughness issues. Fourth, the cushion like effect of the adhesive material causes disruptive impact during backside processing. Fifth, detaching the carrier wafer from the adhesive based bonding requires a complicated process with expensive tooling.

The concepts of the present disclosure address these critical issues that are associated with temporary bonding and provide solutions with a very uniform surface, defect free interface, and a simpler technique to bond/de-bond the device and carrier wafers. In this process, a silicon (Si) carrier wafer with thermal oxide is used with the substantially, if not fully, finished device wafer. In one embodiment, a chemical vapor deposition (CVD) oxide is deposited on the device wafer and planarized to achieve a smooth surface. Initially, the carrier wafer with surface covered with a thermal oxide is ion-implanted with hydrogen ions. The energy and doses are adjusted appropriately to implant hydrogen very close to the surface (about 5-20 nm deep). The implanted face of the carrier wafer is bonded with the front side of the device wafer with CVD oxide by plasma assisted fusion bonding. The plasma assisted fusion bonding process may include plasma treatment, chemical cleaning, and chemical and mechanical polishing. The direct bonding process need not involve any external material but uses the dangling bonds from the surface of the carrier wafer and device wafer to attach them together at low temperature. The bonded wafer is then taken through the backside processing like grinding, polishing, deposition, molding, and/or the like. To achieve the best performance from backside processing, a solid and flat under layer interface is very beneficial. In certain embodiments, fusion bonding offers the highest uniformity with good mechanical support on all the post processing steps due to the absence of any interfacial layer.

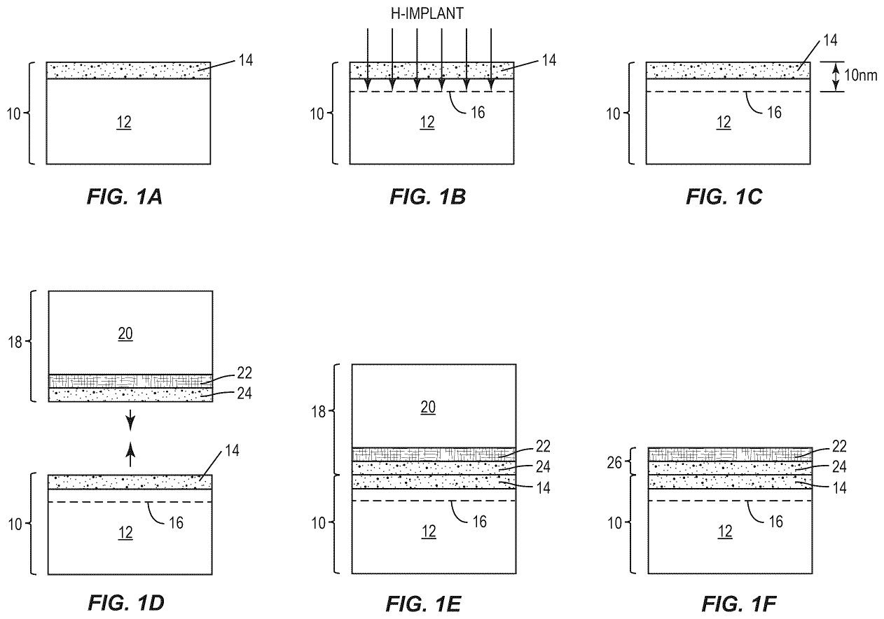

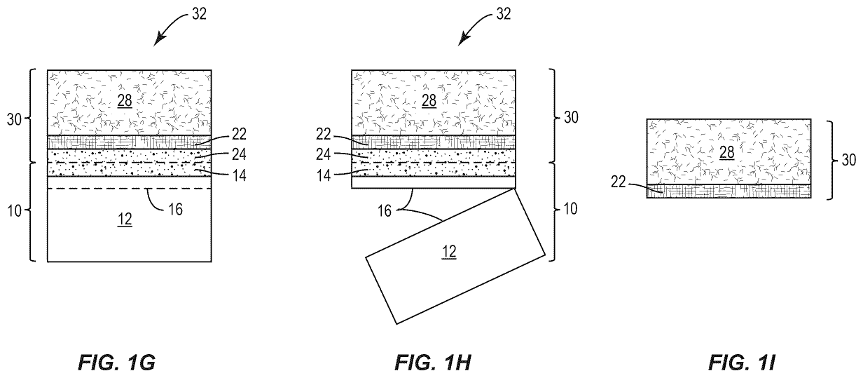

A fabrication process according to one embodiment of the invention is described in association with FIGS. 1A through 1I. With reference to FIG. 1A, a carrier wafer assembly 10, which includes a carrier wafer 12 and a carrier oxide layer 14, is provided. The carrier wafer 12 may be a formed from crystalline silicon and the like. The carrier oxide layer 14 may be formed from silicon dioxide (SiO2) and the like. The oxide layer 14 may be planarized to provide a smooth surface for subsequent processing, as discussed further below. In certain embodiments, the carrier oxide layer 14 has a thickness in the range of 4 to 20 nanometers (nm).

As illustrated in FIG. 1B, the carrier wafer assembly is implanted with hydrogen or the like to form a planar implantation zone 16 below the carrier oxide layer 14 and within the carrier wafer 12. The planar implantation zone 16 is represented by a dashed line and defines a plane at which the carrier wafer 12 will be severed (or cut) into two sections during a subsequent processing step. In certain embodiments, the depth of the planar implantation zone 16 ranges from 4 to 20 nm, as illustrated in FIG. 1C.

Turning now to FIG. 1D, a device wafer assembly 18 is provided in an inverted orientation over the carrier wafer assembly 10. Those skilled in the art will appreciate that the device wafer assembly 18 will generally include a handle wafer 20 and a device layer 22. The handle wafer 20 is typically formed from silicon dioxide and the like, while the device layer 22 may be formed from one more metal layers and semiconductor material in which one or more semiconductor devices and/or circuits are formed. In one embodiment, the device layer 18 may be a substantially or fully processed CMOS (complementary metal oxide semiconductor) structure that provides any number of CMOS devices, circuits, and the like. As defined herein, the device layer 22 may also include one or more interconnects to facilitate external connection for the above-mentioned semiconductor devices and/or circuits. The device wafer assembly 18 may also include a device oxide layer 24 over the device layer 22, wherein the device layer 22 resides between the handle wafer 20 and the device oxide layer 24. The exposed surface of the device oxide layer 24 is planarized. The device oxide layer 24 may be formed from silicon dioxide (SiO2) and the like. In certain embodiments, the device oxide layer 24 has a thickness in the range of 100 to 200 nanometers (nm).

As illustrated in FIG. 1E, the device wafer assembly 18 and the carrier wafer assembly 10 are bonded together. In particular, the planarized surface of the device oxide layer 24 is bonded to the planarized surface of the carrier oxide layer 14. The bonding process may employ a low temperature bonding process, such as plasma-assisted fusion bonding, other low temperature process to achieve permanent bonding below 400 Celsius, or the like. A low temperature bonding process is defined herein as one that facilitates bonding at or below 400 Celsius.

Once the device wafer assembly 18 and the carrier wafer assembly 10 are bonded together, at least a portion of the handle wafer 20 is removed from the backside of the device wafer assembly 18, as illustrated in FIG. 1F. The remaining portion of the device wafer assembly 18 is referred to as a device precursor assembly 26. Removal of a portion of the handle wafer 20 generally corresponds to removing a majority of the handle wafer 20; however, remnants or a residual layer of the handle wafer 20 may remain after the removal process. The removal process may include grinding, chemical and metal polishing (CMP) processing, or a combination thereof. The device layer 22 remains intact.

After at least a portion of the handle wafer 20 is removed, a mold compound 28 is provided over the backside of the device precursor assembly 26 to create a final device precursor 30, as illustrated FIG. 1G. The mold compound 28 may be formed from an epoxy, epoxy mold compound, any polymeric compound, or the like, as those skilled in the art will appreciate.

As illustrated in FIG. 1H, the portion of the carrier wafer assembly 10 below the planar implantation zone 16 is removed from the final device assembly 30. In one embodiment, the removal is facilitated by initially annealing, or heating, the combined final device precursor 30 and the carrier wafer assembly 10 a temperature sufficient to structurally weaken the carrier wafer 12 along the planar implantation zone 16. During the annealing process, a very specific type of platelet structure is formed along the planar implantation zone 16, which eventually leads to blistering along the planar implantation zone 16. Once the blistering occurs, known cleavage techniques may be used to separate or simply remove the carrier wafer assembly 10 from final device precursor 30, as shown in FIG. 1I.

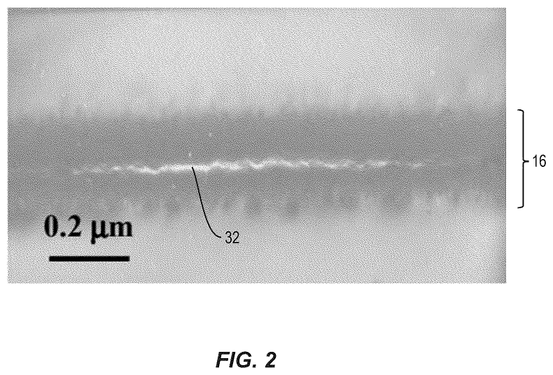

FIG. 2 is a transmission electron microscopy (TEM) image that shows the blistering or microcracking 32 along the planar implantation zone 16 within the carrier wafer 12 after annealing. The annealing temperature may occur around 350 Celsius. Annealing ranges are generally kept low to avoid damaging the semiconductor device and/or circuitry formed within the device layer 22. In certain embodiments, the annealing temperatures are kept at or below 400 Celsius, and often in ranges 350 to 400 Celsius. The process of creating the planar implantation zone 16 and using an annealing process to effectively generate a microcrack at which the respective pieces of a material can be separated is referred to as a smart-cut process.

The front side of the final device assembly 30 may be polished to remove any residue of the carrier wafer 12 as well as some or all of the carrier oxide layer 14, as illustrated in FIG. 1I. The final device assembly 30 may proceed to a passivation opening process to reveal the top metal layer, followed by typical redistribution metal layers and/or bumping processes (solder bump, copper (Cu) pillar bump, wafer level chip scale package (WLCSP) bump), as needed, and then singulation to separate the final device assembly 30 into individual components.

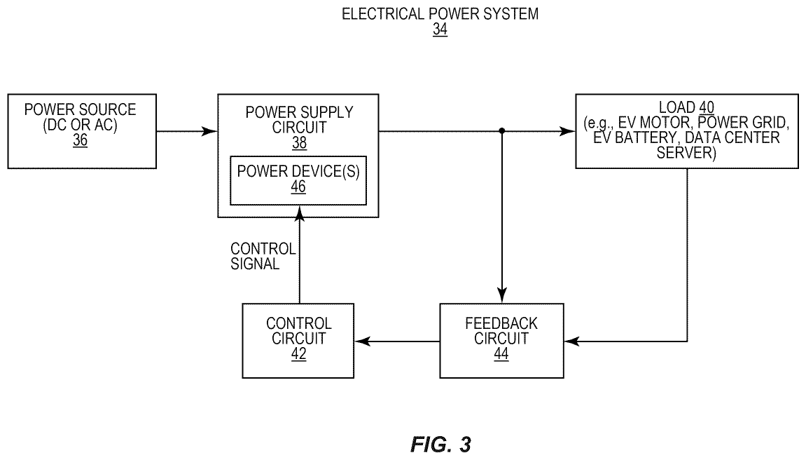

Turning now to FIG. 3, a block diagram of an electrical power system 34 is illustrated. The electrical power system 34 includes a power source 36, a power supply circuit 38, a load 40, a control circuit 42, and a feedback circuit 44. The power source 36 may be an AC (alternating current) or DC (direct current) source or system that delivers power to the power supply circuit 38. The power supply circuit 38 may include one or more power devices 46, such as diodes, transistors, or the like that are formed from the above-described process. The power supply circuit 38, under the control of the control circuit 42, delivers power signals to the load 40 at desired voltage, current, and/or power levels and signal characteristics. The feedback circuit 44 may monitor the power signals, feedback from the load 40, etc. and generate feedback signals to the control circuit 42, which may use the feedback signals along with defined control parameters to generate a control signal that controls the power supply circuit 38. The electrical power system 34 may take many forms and be used in many applications, such as electric vehicles, power grids, solar generation systems, motor control systems, battery charging systems, server systems, and the like.

Those skilled in the art will recognize improvements and modifications to the preferred embodiments of the present disclosure. All such improvements and modifications are considered within the scope of the concepts disclosed herein and the claims that follow.

What is claimed is:

1. A method comprising:
providing a carrier wafer assembly that comprises a carrier wafer and a carrier oxide layer over the carrier wafer, wherein the carrier wafer comprises a planar implantation zone below the carrier oxide layer;
providing a device wafer assembly that comprises a handle wafer, a device layer on the handle wafer, and a device oxide layer on the device layer, wherein the device layer has at least one semiconductor device formed therein;
bonding the carrier wafer assembly to the device wafer assembly such that the carrier oxide layer is bonded to the device oxide layer to form a final device precursor;
annealing the final device precursor to structurally weaken the carrier wafer along the planar implantation zone; and
separating the carrier wafer assembly from the final device precursor at the planar implantation zone.

2. The method of claim 1 comprising implanting the carrier wafer with an implant material to form the planar implantation zone.

3. The method of claim 2 wherein the implant material comprises hydrogen.

4. The method of claim 2 wherein the planar implantation zone is between four (4) and twenty (20) nanometers below a top surface of the carrier oxide layer.

5. The method of claim 4 wherein the implant material comprises hydrogen.

6. The method of claim 5 wherein the carrier oxide layer has a thickness in a range of 4 to 20 nanometers.

7. The method of claim 1 wherein the carrier oxide layer comprises silicon dioxide (SiO₂).

8. The method of claim 1 wherein the device oxide layer comprises silicon dioxide (SiO₂).

9. The method of claim 8 wherein the carrier oxide layer comprises silicon dioxide (SiO₂).

10. The method of claim 1 wherein the device layer is a complementary metal oxide semiconductor (CMOS) device structure that provides at least one CMOS device.

11. The method of claim 1 further comprising removing at least a portion of the handle wafer from a backside of the device wafer assembly.

12. The method of claim 11 further comprising providing a mold compound over the backside of the device wafer assembly after the at least a portion of the handle wafer is removed from the backside of the device wafer assembly.

13. The method of claim 12 wherein the at least a portion of the handle wafer is removed and the mold compound is provided prior to separating the carrier wafer assembly from the final device precursor at the planar implantation zone.

14. The method of claim 1 wherein the step of bonding the carrier wafer assembly to the device wafer assembly employs plasma assisted fusion bonding and occurs at or below 350 Celsius.

15. The method of claim 1 wherein the step of separating the carrier wafer assembly from the final device precursor occurs at or below 400 Celsius.

16. The method of claim 1 wherein the step of bonding the carrier wafer assembly to the device wafer occurs at or below 350 Celsius, and the step of separating the carrier wafer assembly from the final device precursor occurs at or below 400 Celsius.

17. A semiconductor device formed by a process comprising:
providing a carrier wafer assembly that comprises a carrier wafer and a carrier oxide layer over the carrier wafer, wherein the carrier wafer comprises a planar implantation zone below the carrier oxide layer;
providing a device wafer assembly that comprises a handle wafer, a device layer on the handle wafer, and a device oxide layer on the device layer, wherein the device layer has at least one semiconductor device formed therein;
bonding the carrier wafer assembly to the device wafer assembly such that the carrier oxide layer is bonded to the device oxide layer to form a final device assembly;
annealing the final device assembly to structurally weaken the carrier wafer along the planar implantation zone; and
separating the carrier wafer assembly from the final device assembly at the planar implantation zone.

18. The semiconductor device of claim 17 wherein the process further comprises implanting the carrier wafer with an implant material to form the planar implantation zone.

19. The semiconductor device of claim 18 wherein the process further comprises removing at least a portion of the handle wafer from a backside of the device wafer assembly.

20. The semiconductor device of claim 19 wherein the process further comprises providing a mold compound over the backside of the device wafer assembly after the at least a portion of the handle wafer is removed from the backside of the device wafer assembly.

21. Power supply circuitry comprising a semiconductor device formed by a process comprising:
providing a carrier wafer assembly that comprises a carrier wafer and a carrier oxide layer over the carrier wafer, wherein the carrier wafer comprises a planar implantation zone below the carrier oxide layer;
providing a device wafer assembly that comprises a handle wafer, a device layer on the handle wafer, and a device oxide layer on the device layer, wherein the device layer has at least one semiconductor device formed therein;
bonding the carrier wafer assembly to the device wafer assembly such that the carrier oxide layer is bonded to the device oxide layer to form a final device assembly;
annealing the final device assembly to structurally weaken the carrier wafer along the planar implantation zone; and
separating the carrier wafer assembly from the final device assembly at the planar implantation zone.
